(19) United States
(12) Patent Application Publication
(10) Pub. No.: US 2007/0240977 A1
(43) Pub. Date: Oct. 18, 2007

(54) Sputtering with cooled target

(75) Inventors: Joerg Krempel-Hesse, Eckartsborn (DE); Anke Hellmich, Kahl (DE); Gerd Orgeich, Freigericht (DE); Thomas Hegemann, Freigericht (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials GmbH & Co. KG, Alzenau (DE)

(21) Appl. No.: 11/708,661

(22) Filed: Feb. 20, 2007

(30) Foreign Application Priority Data
Feb. 22, 2006 (EP) 06110305.7

(51) Int. Cl. C23C 14/34

(52) U.S. Cl. 204/192.1; 204/298.02

(57) ABSTRACT

The present invention concerns a device and a method for coating substrates by means of sputtering a coating material in the form of a target, wherein the target is cooled during sputtering by means of a cooling medium fed at the target or past the region of the target or through the target, and the cooling medium has a feed temperature of less than 20° C.

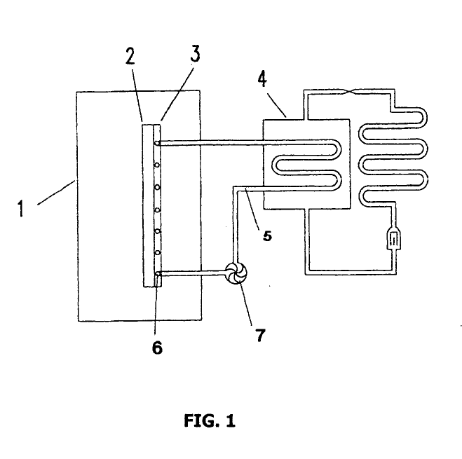

### CROSS-REFERENCE TO RELATED APPLICATIONS

This application claims priority under 35 U.S.C. § 119(a) to EP06110305.7, filed Feb. 22, 2006, the entire disclosure of which is incorporated hereby by reference for all purposes.

### TECHNICAL FIELD

The present invention relates to a method in accordance with the generic part of claim 1 and a device in accordance with the generic part of claim 9.

### PRIOR ART

Sputtering methods for coating substrates in which ions are generated by a plasma in a vacuum chamber where they are accelerated in the direction of the cathode and impinge there on the material for sputtering, namely the coating material, in the form of a target, are generally known. Also known in this regard is the use of so-called magnetrons with which improved sputtering and thus higher coating rates are facilitated by the formation of a magnetic field in the region of the target. Especially, movable magnet arrangements are also known which serve the purpose of improved utilization of the target and thus of the coating material. A corresponding device for this is described, for example, in EP 063 45 00 B1, the entire disclosure of which is incorporated hereby by reference for all purposes.

In order that the heat generated on the target by the impingement of the ions may be dissipated, it is also the prior art to provide corresponding cooling devices in which a coating medium is passed through or past the region of the target to dissipate the generated heat. This, too, is described for example in EP 063 45 00 B1 and DE 199 16 938 A1, the entire disclosures of both of which are incorporated herein by reference for all purposes.

The usual coating medium for this is water, which is introduced at room temperature into the cooling channels in the region of the target.

Although the aforementioned sputtering methods and devices for this yield predominantly satisfactory results, it has been observed that, especially in the case of certain coating materials or target materials, such as indium tin oxide (ITO) or generally in the case of transparent conductive oxides or ceramic targets, the problem of so-called nodule formation at the target surface occurs. The nodules, which form at the target surface, are formed from an extremely hard substance that negatively influences the further sputtering process and, especially in the case of substrates lying beneath the target, leads to impairment of layer quality due to subsequent spalling from the target surface.

To master this problem, methods are described in the prior art that propose increasing the target temperatures to values of more than 100° C. (JP 020 509 51 A), more than 200° C. (DE 100 18 842 C2) and even to values of more than 400-500° C. (JP 05 34 59 73 A). This means that, in such methods, the targets are no longer being cooled, but rather heated in order that the undesirable nodule formation may be counteracted. However, this has not led to any satisfactory results overall.

### DISCLOSURE OF THE INVENTION

### Technical Object

It is therefore the object of the present invention to provide a method and a device for sputtering processes that make it possible to counteract the disadvantageous nodule formation on targets, especially in the case of ceramic targets, preferably targets for deposition of conductive, transparent oxides and especially indium tin oxide targets in a simple and efficient manner.

### Technical Solution

This object is achieved by a method having the features of claim 1 and a device having the features of claim 9. Advantageous embodiments are the object of the dependent claims.

The inventors have surprisingly found that nodule formation can be effectively counteracted by substantially lowering the target temperature. This can be achieved by providing a cooling medium with a feed temperature of less than 20° C. to cool the target. The lower the target temperature or the feed temperature of the cooling medium, the less pronounced is the extent of nodule formation. Approximately 80-90% of the electrical energy introduced into the sputtering cathode has to be dissipated with the cooling medium in order that the target may be adequately cooled. This energy input into the cooling medium can lead to extensive heating of the cooling medium, especially in the case of magnetron cathodes of large length or in the case of high sputtering power, so that the target close to the cooling medium inlet still has the desired temperature, but that temperature overheating can occur as the cooling medium outlet is approached more and more. This temperature overheating can, in turn, have the consequence that nodule formation on the erosion face of the target in the region of the cooling medium inlet is suppressed in accordance with the invention, increases steadily in a central region and occurs to the same extent as in the prior art in the region of the cooling medium outlet. To suppress nodule formation effectively on the entire target surface, it should therefore preferably be ensured that the heating sections for the cooling medium are kept sufficiently short by appropriate measures, a condition that, for example, can be achieved by providing several separate cooling circuits along the target length. For this reason, it is also advantageous for not only the temperature of the cooling medium feed, but (also) that of the cooling medium return for the individual cooling circuits to be monitored or to be kept below a certain temperature by means of a closed-loop control.

It has especially proved advantageous to provide a cooling medium with a feed and/or return temperature of less than 5° C., i.e. barely in the vicinity of the freezing point or beneath it, or markedly lower at minus temperatures of approximately −20° C. or less than −100° C.

Correspondingly, the cooling medium may be both a cooling liquid and a cooling gas, with consideration given especially to water, air, hydrocarbons, especially fluorohydrocarbons, alcohols and the like as well as mixtures thereof, depending on which feed or return temperature is chosen for the cooling medium.

The avoidance or reduction of nodule formation is hereby ensured in all targets or coating materials that tend to undergo nodule formation, especially in the deposition of oxide layers, preferably transparent, conductive oxide layers, such as tin or zinc oxide layers, especially indium tin oxide layers.

### BRIEF DESCRIPTION OF THE DRAWINGS

Further advantages, characteristics and features of the present invention are apparent from the following description of a preferred embodiment using the enclosed drawing. The FIGURE shows in a schematic diagram the essential components of a sputtering device in accordance with the invention.

### THE BEST EMBODIMENT OF THE INVENTION

In the enclosed diagram, the essential components of a device in accordance with the invention for performing the method in accordance with the invention are shown schematically.

The diagram shows a vacuum chamber 1 in which the substrate (not shown) is coated by sputtering a target 2 by means of ions generated in the plasma. The target 2 is arranged on a so-called target backing plate 3, which is punctuated by cooling channels 6. The cooling channels 6 are connected to a line 5 in which a pump 7 is arranged such that, in the closed circuit of line 5, a cooling medium can be pumped in a loop, said cooling medium flowing through the cooling channels 6 of the target backing plate 3 and thus dissipating the heat generated by the ions when the target 2 is bombarded.

The line 5 winds its way in loops through a heat exchanger of a cooling unit 4, such that the cooling medium can be cooled to a certain feed temperature, which the cooling medium has on entering the cooling channels 6 of the target backing plate 3. The return temperature of the cooling medium, after the medium has passed through the cooling channels 6 in the target backing plate 3, is increased by absorption of the heat from target 2 and is lowered to the desired feed temperature again in the heat exchanger of the cooling unit 4.

The cooling medium line 5 has an insulated design, especially in the region between the heat exchanger of the cooling unit 4 and the cooling channels 6 of the target backing plate 3 in order that premature heating of the cooling medium may be ruled out and water of condensation avoided.

In the preferred embodiment, an indium tin oxide (ITO) target 2 was sputtered in an argon/oxygen atmosphere at a pressure of approx 5×10⁻³ mbar and a power of 19 kW and deposited on the substrate, with the feed temperature, i.e. the inlet temperature of the cooling medium into the cooling channels 6 of the target backing plate 3, being 5° C. and the return temperature 11° C. The flow-through rate of the cooling medium was approximately 18 liters per minute, with water used as the cooling medium.

The target 2 was used in a planar magnetron cathode, not described in any more detail, with a movable magnet arrangement.

In comparison to a sputtering trial with a cooling medium feed temperature of 21° C., a substantially reduced number of so-called nodules was observed on the target.

Although water was used as the cooling medium in the embodiment described, other cooling media, especially liquids that remain liquid at minus temperatures, as well as cooling gases, may also be used. It was especially noticed that progressive reductions in the target temperature or of the feed temperature lead to a further reduction in the number of nodules, so that especially temperatures of below 0° C., preferably −20° C. or −100° C. appear particularly attractive. Especially, commercial cooling devices capable of temperatures of −120° C. are available.

Although an indium tin oxide target in an argon atmosphere with a low proportion of oxygen was used in the embodiment described, a most diverse range of target materials, such as pure metals, or other compounds, such as oxide, may be used, in pure inert atmospheres, or with the addition of reactive agents (reactive sputtering).

Although in the preferred embodiment, the target is provided on a target backing plate, targets without backing plate 3 are especially also conceivable, wherein the cooling channels 6 may be provided directly at the target 2, such as is partially the case in the prior art described in the introduction.

1. Method for coating substrates, the method comprising:
sputtering a coating material in the form of a target;
cooling the target during sputtering by feeding a cooling medium past the target or in the region of the target or through the target; and
depositing oxide layers with the cooling medium having a feed and/or return temperature of less than 5° C.

2. Method for coating substrates, the method comprising:
sputtering a coating material in the form of a target;
cooling the target during sputtering by feeding a cooling medium past the target or in the region of the target or through the target; and
performing reactive sputtering with the use of a reactive substance,
wherein the cooling medium has a feed and/or return temperature of less than 5° C.

3. Method in accordance with claim 1 wherein the cooling medium has a feed and/or return temperature of less than 0°.

4. Method in accordance with claim 1, wherein the cooling medium is a cooling liquid or cooling gas selected from the group consisting of water, air, hydrocarbons, fluorohydrocarbons, alcohols and mixtures thereof.

5. Method in accordance with claim 1, wherein the method is performed in a high vacuum and/or with the use of magnetron sputtering sources.

6. Method in accordance with claim 1, wherein reactive sputtering is performed with the use of a reactive substance.

7. Method in accordance with claim 1, further comprising
depositing transparent, conductive oxide layers.

8. Method in accordance with claim 1, wherein the target comprises an oxide targets.

9. Device for coating substrates comprising:
a cooling unit, which is set up to provide a cooling medium for direct or indirect cooling of a target at a feed and/or return temperature of less than 5° C.; and
means for reactive sputtering of the target.

10. Device in accordance with claim 9, wherein the cooling unit is set up such that the cooling medium has a feed and/or return temperature of less than 0° C.

11. Device in accordance with claim 9 wherein the cooling medium is a cooling liquid or cooling gas selected from the group consisting of water, air, hydrocarbons, fluorohydrocarbons, alcohols and mixtures thereof.

12. Device in accordance with claim 9, wherein the cooling device has an open-loop and/or closed-loop unit for open-loop and/or closed-loop control of the feed and/or return temperature.

13. Device in accordance with claim 9, wherein the cooling device comprises one or more cooling circuits that are independent of each other.

14. Method in accordance with claim 1, wherein the cooling medium has a feed and/or return temperature of less than 0° C.

15. Method in accordance with claim 1, wherein the cooling medium has a feed and/or return temperature of less than −20° C.

16. Method in accordance with claim 1, wherein the cooling medium has a feed and/or return temperature of less than −100° C.

17. Method in accordance with claim 5, wherein the magnetron sputtering sources comprise planar magnetron sputtering sources and/or magnetron sputtering sources fitted with a moveable magnet arrangement.

18. Method in accordance with claim 6, wherein the reactive substance comprises a reactive gas for the sputtered coating material.

19. Method in accordance with claim 7, wherein the transparent, conductive oxide layers comprise tin and/or zinc oxide layers.

20. Method in accordance with claim 19, wherein the transparent, conductive oxide layers comprise indium tin oxide (ITO) layers.

21. Method in accordance with claim 8, wherein the oxide target comprises a transparent, conductive oxide target.

22. Method in accordance with claim 21, wherein the oxide target comprises a tin and/or zinc oxide target.

23. Method in accordance with claim 22, wherein the oxide target comprise s an indium tin oxide target.

24. Method in accordance with claim 2, wherein the cooling medium has a feed and/or return temperature of less than 0° C.

25. Method in accordance with claim 2, wherein the cooling medium has a feed and/or return temperature of less than −20° C.

26. Method in accordance with claim 2, wherein the cooling medium has a feed and/or return temperature of less than −100° C.

27. Method in accordance with claim 2, wherein the cooling medium is a cooling liquid or cooling gas selected from the group consisting of water, air, hydrocarbons, fluorohydrocarbons, alcohols and mixtures thereof.

28. Method in accordance with claim 2, wherein the method is performed in a high vacuum and/or with the use of magnetron sputtering sources.

29. Method in accordance with claim 28, wherein the magnetron sputtering sources comprise planar magnetron sputtering sources and/or magnetron sputtering sources fitted with a moveable magnet arrangement.

30. Method in accordance with claim 2, further comprising depositing transparent, conductive oxide layers.

31. Method in accordance with claim 30, wherein the transparent, conductive oxide layers comprise tin and/or zinc oxides.

32. Method in accordance with claim 31, wherein the transparent, conductive oxide layers comprise indium tin oxide (ITO) layers.

33. Method in accordance with claim 2, wherein the target comprises an oxide target.

34. Method in accordance with claim 33, wherein the oxide target comprises a tin and/or zinc oxide target.

35. Method in accordance with claim 34, wherein the oxide target comprises an indium tin oxide target.

36. Device in accordance with claim 9, wherein the cooling unit is set up such that the cooling medium has a feed and/or return temperature of less than −20° C.

37. Device in accordance with claim 9, wherein the cooling unit is set up such that the cooling medium has a feed and/or return temperature of less than −100° C.
